(19) United States
(12) Patent Application Publication
(10) Pub. No.: US 2025/0341561 A1
(43) Pub. Date: Nov. 6, 2025

(54) INSPECTION APPARATUS, INSPECTION SYSTEM, INSPECTION METHOD, AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Masaru FURUKAWA, Himeji Hyogo (JP)

(21) Appl. No.: 19/269,506

(22) Filed: Jul. 15, 2025

Related U.S. Application Data
(63) Continuation of application No. PCT/JP2024/004151, filed on Feb. 7, 2024.

(30) Foreign Application Priority Data
Sep. 15, 2023 (JP) 2023-150217

(51) Int. Cl. G01R 31/26; H01L 21/66

(52) U.S. Cl. CPC G01R 31/2607; H01L 22/14

(57) ABSTRACT

According to one embodiment, an inspection apparatus includes a controller configured to be electrically connected to a semiconductor device. The semiconductor device includes a semiconductor member, a transistor section, and a diode section. The transistor section and the diode section are provided in the semiconductor member. The transistor section includes a source electrode, a drain electrode, and a gate electrode. The diode section includes a first end and a second end. The first end is electrically connected to the source electrode. The second end is electrically connected to the drain electrode. The controller is configured to perform a first operation, a first progress operation, a second operation, and a first determination operation. The first progress operation is performed after the first operation. The second operation is performed after the first progress operation.

### CROSS-REFERENCE TO RELATED APPLICATIONS

This is a continuation application of International Application PCT/JP2024/004151, filed on Feb. 7, 2024. This application also claims priority to Japanese Patent Application No. 2023-150217, filed on Sep. 15, 2023. The entire contents of which are incorporated herein by reference.

### FIELD

Embodiments described herein generally relate to an inspection apparatus, an inspection system, an inspection method, and a method for manufacturing a semiconductor device.

### BACKGROUND

For example, in the manufacture of semiconductor devices, the semiconductor devices are inspected. Improvement in inspection efficiency is desired.

### BRIEF DESCRIPTION OF THE DRAWINGS

FIG. 1 is a schematic diagram illustrating an inspection apparatus according to a first embodiment;

FIG. 2 is a flowchart illustrating the operation of the inspection apparatus according to the first embodiment;

FIGS. 3A and 3B are schematic diagrams illustrating the operation of the inspection apparatus according to the first embodiment; and

FIG. 4 is a flowchart illustrating a method for manufacturing a semiconductor device according to a fourth embodiment.

### DETAILED DESCRIPTION

According to one embodiment, an inspection apparatus includes a controller configured to be electrically connected to a semiconductor device. The semiconductor device includes a semiconductor member, a transistor section, and a diode section. The transistor section and the diode section are provided in the semiconductor member. The transistor section includes a source electrode, a drain electrode, and a gate electrode. The diode section includes a first end and a second end. The first end is electrically connected to the source electrode. The second end is electrically connected to the drain electrode. The controller is configured to perform a first operation, a first progress operation, a second operation, and a first determination operation. The first progress operation is performed after the first operation. The second operation is performed after the first progress operation. In the first operation, the controller is configured to set the gate electrode to an on-potential and to detect a first detection value of a drain potential of the drain electrode in a state where a current source is electrically connected to the drain electrode. The current source is configured to supply a first current to the drain electrode in a direction from the drain electrode to the source electrode. In the first progress operation, the controller is configured to set the gate electrode to an off-potential in a state where the current source is electrically connected to the drain electrode. In the second operation, the controller is configured to set the gate electrode to the on-potential and to detect a second detection value of the drain potential in a state where the current source is electrically connected to the drain electrode. In the first determination operation, the controller is configured to inspect the semiconductor device based on a difference between the first detection value and the second detection value.

Various embodiments are described below with reference to the accompanying drawings.

In the specification and drawings, components similar to those described previously in an antecedent drawing are marked with like reference numerals, and a detailed description is omitted as appropriate.

### First Embodiment

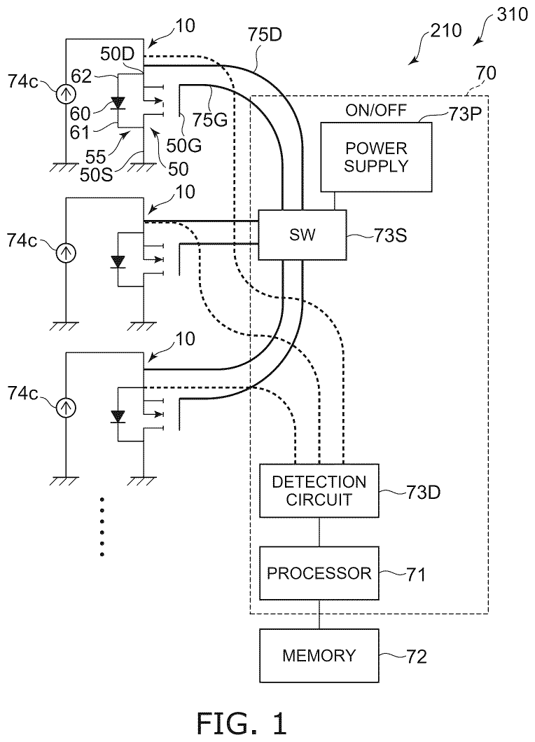

FIG. 1 is a schematic diagram illustrating an inspection apparatus according to a first embodiment.

As shown in FIG. 1, an inspection apparatus 210 according to the embodiment includes a controller 70. The controller 70 configured to be electrically connected to a semiconductor device 10 to be inspected. The inspection apparatus 210 may further include a memory 72. The memory 72 may be provided separately from the inspection apparatus 210. The memory 72 may be provided at a location different from where the controller 70 is provided. The inspection system 310 according to the embodiment includes a controller 70 and a memory 72.

As shown in FIG. 1, the semiconductor device 10 includes a semiconductor member 55, a transistor section 50, and a diode section 60. The transistor section 50 and the diode section 60 are provided in the semiconductor member 55. The transistor section 50 is provided in a portion of the semiconductor member 55, and the diode section 60 is provided in another portion of the semiconductor member 55. For example, the semiconductor device 10 is a transistor that includes a diode section 60. The transistor section 50 and the diode section 60 are provided on one chip.

The semiconductor member 55 includes, for example, SiC. For example, the diode section 60 may be a Schottky diode.

The transistor section 50 includes a source electrode 50S, a drain electrode 50D, and a gate electrode 50G. The diode section 60 includes a first end 61 and a second end 62. The first end 61 is electrically connected to the source electrode 50S. The second end 62 is electrically connected to the drain electrode 50D. The first end 61 is common to the source electrode 50S. The second end 62 is common to the drain electrode 50D.

For example, the inspection apparatus 210 may include multiple probes. For example, the inspection apparatus 210 includes a drain probe 75D and a gate probe 75G. The drain probe 75D is configured to be electrically connected to drain electrode 50D. The gate probe 75G is configured to be electrically connected to gate electrode 50G. The source electrode 50S may be electrically connected to the controller 70 via, for example, a ground conductive member.

A voltage is applied to the semiconductor device 10 via these probes, and the semiconductor device 10 is tested.

As shown in FIG. 1, a plurality of semiconductor devices 10 may be inspected. In this case, a plurality of drain probes 75D, a plurality of gate probes 75G, etc. may be provided.

As shown in FIG. 1, in the inspection apparatus 210, the controller 70 may include a power supply 73P, a switch section 73S, a detection circuit 73D, and the like. In various operations described below, the switch section 73S applies the gate voltage from the power supply 73P to the gate electrode 50G at a desired timing.

The detection circuit 73D is configured to detect, for example, the potential of the drain electrode 50D. The detection circuit 73D is configured to detect values related to the electrical characteristics of the semiconductor device 10, for example, based on timings in various operations described below. For example, operations based on interlock signals may be implemented. For example, a synchronization signal may be supplied from the switch section 73S to the detection circuit 73D.

As shown in FIG. 1, a current source 74c may be provided. The current source 74c is electrically connected to the drain electrode 50D. The current source 74c is configured to supply a first current to the drain electrode 50D in a direction from the drain electrode 50D to the source electrode 50S. The operation of the current source 74c may be controlled by, for example, the detection circuit 73D.

The power supply 73P may be prepared separately from the inspection apparatus 210. The power supply 73P may be included in inspection apparatus 210. The current source 74c may be prepared separately from the inspection apparatus 210.

The current source 74c may be included in inspection apparatus 210.

As shown in FIG. 1, a processor 71 may be provided. As shown in FIG. 1, the memory 72 may be provided. The processor 71 is configured to process various data. For example, the processor 71 is configured to process the detected value. The processor 71 may cause the memory 72 to store the processed value. The processor 71 may be able to perform a process of comparing a value based on the detected value with a reference value or the like. For example, the comparison result corresponds to the inspection result of the semiconductor device 10.

The processor 71 may be included in the controller 70. The processor 71 may be provided at a location different from the location where the switch section 73S and the like are provided. The memory 72 may be included in the controller 70. The memory 72 may be provided at a location different from the location where the switch section 73S and the like are provided. The controller 70 is configured to inspect the semiconductor device 10 through operations described below.

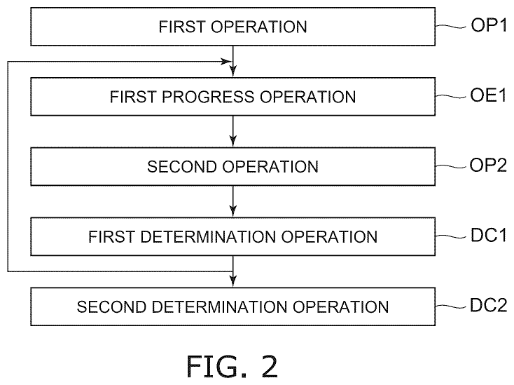

FIG. 2 is a flowchart illustrating the operation of the inspection apparatus according to the first embodiment.

As shown in FIG. 2, in the inspection apparatus 210, the controller 70 is configured to perform a first operation OP1, a first progress operation OE1, a second operation OP2, and a first determination operation DC1. The first progress operation OE1 is performed after the first operation OP1. The second operation OP2 is performed after the first progress operation OE1. The first determination operation DC1 is performed after the second operation OP2. A second determination operation DC2 may be further performed. Examples of these operations will be described below.

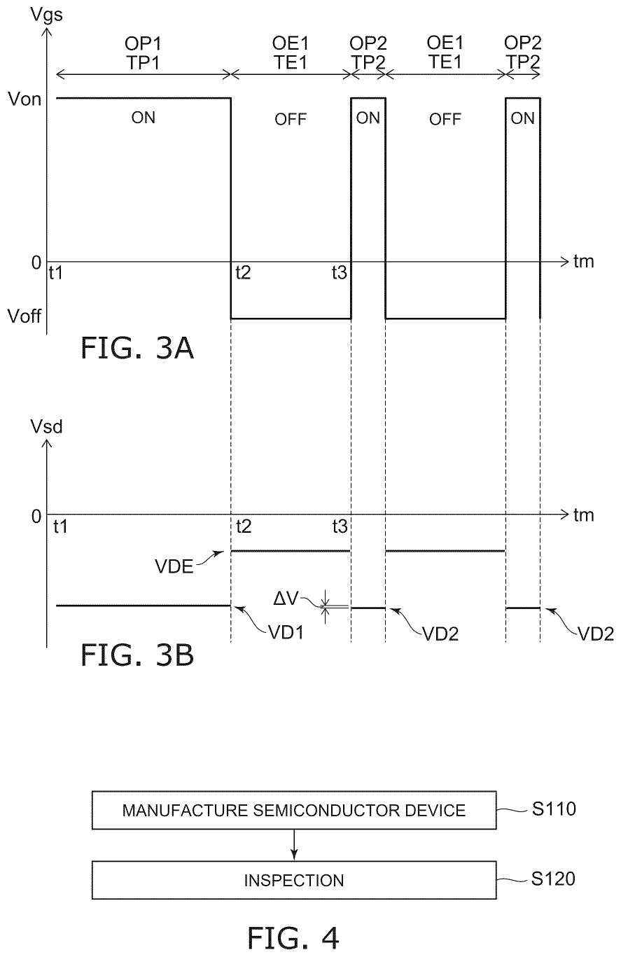

FIGS. 3A and 3B are schematic diagrams illustrating the operation of the inspection apparatus according to the first embodiment.

These figures correspond to time charts of the operations. The horizontal axis of these figures is time tm. The vertical axis in FIG. 3A is a gate voltage Vgs. The gate voltage Vgs is the voltage of the gate electrode 50G based on the potential of the source electrode 50S. The vertical axis in FIG. 3B is the drain potential Vsd. The drain potential Vsd is the voltage of the drain electrode 50D based on the potential of the source electrode 50S.

As shown in FIG. 1, in the following operation, the current source 74c is electrically connected to the drain electrode 50D. As illustrated in FIG. 3A, in the first operation OP1, the controller 70 sets the gate electrode 50G to an on-potential Von during a first period TP1 in a state where the current source 74c is electrically connected to the drain electrode 50D. In the first operation OP1, the current source 74c is configured to supply the drain electrode 50D with the first current in the direction from the drain electrode 50D toward the source electrode 50S. The first period TP1 is, for example, a period from a first time t1 to a second time t2.

As shown in FIG. 3B, the controller 70 detects a first detection value VD1 of the drain potential Vsd of the drain electrode 50D in the first operation OP1. The controller 70 may cause the memory 72 to store the first detection value VD1 in the first operation OP1.

As shown in FIG. 3A, in the first progress operation OE1, the controller 70 sets the gate electrode 50G to the off-potential Voff during a first progress period TE1 in a state where the current source 74c is electrically connected to the drain electrode 50D. The first progress period TE1 is, for example, a period from the second time t2 to the third time t3.

As shown in FIG. 3B, in the first progress period TE1, the drain potential Vsd becomes, for example, a first progress period potential VDE.

As shown in FIG. 3A, in the second operation OP2, the controller 70 sets the gate electrode 50G to the on-potential Von during the second period TP2 in a state where the current source 74c is electrically connected to the drain electrode 50D.

As shown in FIG. 3B, the controller 70 detects a second detection value VD2 of the drain potential Vsd in the second operation OP2. The controller 70 may store the second detection value VD2 in the memory 72.

In the first determination operation DC1, the controller 70 is configured to inspect the semiconductor device 10 based on the difference AV (see FIG. 3B) between the first detection value VD1 and the second detection value VD2.

As described above, in the embodiment, in the first operation OP1, the first detection value VD1 of the drain potential Vsd is detected as an initial value. Thereafter, in the first progress operation OE1, the current source 74c supplies the current to the drain electrode 50D in a state where the gate electrode 50G is set to the off-potential Voff. In the first progress operation OE1, in the semiconductor device 10, there is a case where the state of the semiconductor member 55 changes. For example, holes are injected from the drain electrode 50D into the semiconductor member 55, and crystal defects expand. The expansion of the crystal defects changes the characteristics of the semiconductor device 10. For example, the forward voltage VF changes.

In the second operation OP2 after the first progress operation OE1, the second detection value VD2 of the drain potential Vsd is detected. In the first progress operation OE1, when the state of the semiconductor member 55 changes, the second detection value VD2 changes from the first detection value VD1. On the other hand, in the first progress operation OE1, when the state of the semiconductor member 55 does not substantially change, the second detection value VD2 is substantially the same as the first detection value VD1.

A change in the state of the semiconductor member 55 can be detected based on the difference ΔV between the first detection value VD1 and the second detection value VD2. For example, the difference ΔV is compared to a threshold value. If the difference ΔV is less than or equal to the threshold value, the semiconductor device 10 is determined to be a good product. If the difference ΔV exceeds the threshold value, the semiconductor device 10 is determined to be a defective product. With such a first determination operation DC1, it is possible to test the semiconductor device 10 with high efficiency. According to the embodiment, it is possible to provide an inspection apparatus that can improve efficiency.

For example, there is a first reference example in which a change in the state of the semiconductor member 55 is evaluated by detecting a change in the forward voltage VF. The sensitivity of the change in forward voltage VF detected in the first reference example is low. Therefore, in the first reference example, it is difficult to detect a change in the state of the semiconductor member 55 with high sensitivity.

On the other hand, in the embodiment, the first detection value VD1 and the second detection value VD2 are detected while the on-potential Von is applied to the gate electrode 50G. These detected values reflect the characteristics of the on-resistance Ron. The sensitivity of changes in these detected values is high. In the embodiment, a highly sensitive result is possible by evaluating the difference ΔV between the first detection value VD1 and the second detection value VD2.

In the embodiment, the operation in the synchronous rectification mode illustrated in FIGS. 3A and 3B is performed. The rectification is performed in synchronization with turning on and off the gate voltage Vgs. Highly accurate detection can be performed with high efficiency.

For example, in a MOS transistor including a reverse conducting diode, when the reverse conducting diode is energized, crystal defects present in the semiconductor member 55 (for example, the SiC layer) expand. When the crystal defects expand, the forward voltage VF increases and the on-resistance Ron increases. In the embodiment in which a chip in which such a characteristic variation due to energization of the reverse conducting diode occurs is excluded by inspection, it is possible to provide an inspection apparatus capable of efficiently detecting defective products.

In FIG. 3A, the on-potential Von and the off-potential Voff may satisfy the following first condition or second condition. In the first condition, the on-potential Von is positive with respect to the source potential of the source electrode 50S. In the first condition, the off-potential Voff is negative with respect to the source potential.

In the second condition, the on-potential Von and the off-potential Voff are positive with respect to the source potential. In the second condition, the first difference between the off-potential Voff and the source potential is smaller than the second difference between the on-potential Von and the source potential.

In one example, the on-potential Von may be not less than +10V and not more than +30V (e.g., +15V). In one example, the off-potential Voff may be not less than −8V and not more than −1V (for example, −5V).

In the embodiment, the first progress period TE1 is longer than the second period TP2. By the first progress period TE1 being long, crystal defects are efficiently expanded. By the second period TP2 being short, the inspection time can be shortened.

In one example, the first period TP1 is longer than the second period TP2. By the first period TP1 for detecting the initial state being long, the first detection value VD1 can be stably detected.

In one example, the first progress period TE1 may be shorter than the first period TP1.

The length of the first period TP1 may be, for example, not less than 0.1 seconds and not more than 15 seconds. The length of the first progress period TE1 may be, for example, not less than 1 ms and not more than 1 H. The length of the second period TP2 may be, for example, not less than 100 μs and not more than 15 seconds.

For example, the controller 70 may be configured to detect the first detection value VD1 at an arbitrary time in the first period TP1. The controller 70 may be configured to detect the second detection value VD2 at an arbitrary time in the second period TP2.

For example, the controller 70 may be configured to detect the first detection value VD1 at a first end time of the first period TP1. The controller 70 may be configured to detect the second detection value VD2 at a second end time of the second period TP2.

As shown in FIGS. 3A and 3B, the first progress operation OE1 and the second operation OP2 may be repeatedly performed. For example, the controller 70 may be configured to further perform another first progress operation OE1 after the second operation OP2. The controller 70 may be configured to further perform another second operation OP2 after the other first progress operation OE1.

As shown in FIG. 2, the first progress operation OE1, the second operation OP2, and the first determination operation DC1 may be repeatedly performed. The determination (first determination operation DC1) may be performed for each of a plurality of repetitions.

For example, when the number of repeated operations exceeds a predetermined number of times, the second determination operation DC2 may be performed. In the second determination operation DC2, the semiconductor device 10 is inspected based on the results of the plurality of first determination operations DC1. For example, the second determination operation DC2 may be performed based on changes in the results of the plurality of first determination operations DC1.

The controller 70 may be configured to simultaneously perform at least a portion of the first operation OP1 for the plurality of semiconductor devices 10. The controller 70 may be configured to simultaneously perform at least a portion of the first progress operation OE1 for the plurality of semiconductor devices 10. The controller 70 may be configured to simultaneously perform at least a portion of the second operation OP2 for the plurality of semiconductor devices 10. Efficient inspection becomes possible.

### Second Embodiment

The second embodiment relates to an inspection system 310 (see FIG. 1). The inspection system 310 includes the memory 72, and the controller 70 configured to be electrically connected to semiconductor device 10. In the inspection system 310, the controller 70 is configured to perform the above operations. According to the second embodiment, it is possible to provide an inspection system that can improve efficiency.

### Third Embodiment

The third embodiment relates to an inspection method. In the inspection method, at least a portion of the operations described with respect to FIG. 2 are performed. The inspection method according to the third embodiment is an inspection method for inspecting the semiconductor device 10. As described with reference to FIG. 1, the semiconductor device 10 includes the semiconductor member 55, the transistor section 50, and the diode section 60. The transistor section 50 and the diode section 60 are provided in the semiconductor member 55. The transistor section 50 is provided in a portion of the semiconductor member 55, and the diode section 60 is provided in another portion of the semiconductor member 55. The transistor section 50 includes the source electrode 50S, the drain electrode 50D, and the gate electrode 50G. The diode section 60 includes the first end 61 and the second end 62. The first end 61 is electrically connected to the source electrode 50S. The second end 62 is electrically connected to the drain electrode 50D.

In the inspection method according to the third embodiment, the first operation OP1, the first progress operation OE1, the second operation OP2, and the first determination operation DC1 are performed (see FIG. 2). The first progress operation OE1 is performed after the first operation OP1. The second operation OP2 is performed after the first progress operation OE1.

As described with reference to FIG. 3A, in the first operation OP1, in a state where the current source 74c is electrically connected to the drain electrode 50D, the gate electrode 50G is set to the on-potential Von, and the first detection value VD1 of the drain potential Vsd of the drain electrode 50D is detected. The current source 74c supplies the first current to the drain electrode 50D in the direction from the drain electrode 50D to the source electrode 50S.

As shown in FIG. 3A, in the first progress operation OE1, the gate electrode 50G is set to the off-potential Voff in a state where the current source 74c is electrically connected to the drain electrode 50D.

As shown in FIG. 3A, in the second operation OP2, in a state where the current source 74c is electrically connected to the drain electrode 50D, the gate electrode 50G is set to the on-potential Von, and the second detection value VD2 of the drain potential Vsd is detected. In the first determination operation DC1, the semiconductor device 10 is inspected based on the difference ΔV between the first detection value VD1 and the second detection value VD2. According to the embodiment, it is possible to provide an inspection system capable of improving efficiency.

In the third embodiment, the configuration described in relation to the first embodiment or the second embodiment may be applied. For example, the first progress period TE1 of the first progress operation OE1 may be longer than the second period TP2 of the second operation OP2. For example, the first detection value VD1 may be detected at the first end time of the first period TP1 of the first operation OP1, and the second detection value VD2 may be detected at the second end time of the second period TP2 of the second operation OP2.

For example, the on-potential Von and the off-potential Voff may satisfy the first condition or the second condition. In the first condition, the on-potential Von is positive with respect to the source potential of the source electrode 50S, and the off-potential Voff is negative with respect to the source potential. In the second condition, the on-potential Von and the off-potential Voff are positive with respect to the source potential. In the second condition, the first difference between the off-potential Voff and the source potential is smaller than the second difference between the on-potential Von and the source potential.

In the third embodiment as well, the semiconductor member 55 may include SiC. The diode section 60 may be, for example, a Schottky diode.

### Fourth Embodiment

FIG. 4 is a flowchart illustrating a method for manufacturing a semiconductor device according to the fourth embodiment.

As shown in FIG. 4, in a method for manufacturing the semiconductor device 10, the semiconductor device 10 is manufactured (step S110). The inspection method described in connection with the third embodiment is performed (step S120). Thereby, the semiconductor device 10 is inspected. In the fourth embodiment, the semiconductor member 55 included in the semiconductor device 10 includes SiC.

The embodiments may include the following Technical proposals:

### Technical Proposal 1

An inspection apparatus, comprising:
a controller configured to be electrically connected to a semiconductor device,
the semiconductor device including a semiconductor member, a transistor section, and a diode section,
the transistor section and the diode section being provided in the semiconductor member,
the transistor section including a source electrode, a drain electrode, and a gate electrode,
the diode section including a first end and a second end,
the first end being electrically connected to the source electrode,
the second end being electrically connected to the drain electrode,
the controller being configured to perform a first operation, a first progress operation, a second operation, and a first determination operation,
the first progress operation being performed after the first operation,
the second operation being performed after the first progress operation,
in the first operation, the controller being configured to set the gate electrode to an on-potential and to detect a first detection value of a drain potential of the drain electrode in a state where a current source is electrically connected to the drain electrode, the current source supplying a first current to the drain electrode in a direction from the drain electrode to the source electrode,
in the first progress operation, the controller being configured to set the gate electrode to an off-potential in a state where the current source is electrically connected to the drain electrode,
in the second operation, the controller being configured to set the gate electrode to the on-potential and to detect a second detection value of the drain potential in a state where the current source is electrically connected to the drain electrode, and
in the first determination operation, the controller being configured to inspect the semiconductor device based on a difference between the first detection value and the second detection value.

### Technical Proposal 2

The inspection apparatus according to Technical proposal 1, wherein
a first progress period of the first progress operation is longer than a second period of the second operation.

### Technical Proposal 3

The inspection apparatus according to Technical proposal 2, wherein
a first period of the first operation is longer than the second period.

### Technical Proposal 4

The inspection apparatus according to Technical proposal 3, wherein
the first progress period is shorter than the first period.

### Technical Proposal 5

The inspection apparatus according to Technical proposal 1, wherein
the controller is configured to detect the first detection value at an arbitrary time in a first period of the first operation, and
the controller is configured to detect the second detection value at an arbitrary time in a second period of the second operation.

### Technical Proposal 6

The inspection apparatus according to Technical proposal 1, wherein
the controller is configured to detect the first detection value at a first end time of a first period of the first operation, and
the controller is configured to detect the second detection value at a second end time of a second period of the second operation.

### Technical Proposal 7

The inspection apparatus according to any one of Technical proposals 1-6, further comprising:
the current source.

### Technical Proposal 8

The inspection apparatus according to any one of Technical proposals 1-7, wherein
the on-potential and the off-potential satisfy a first condition or a second condition,
in the first condition, the on-potential is positive with respect to a source potential of the source electrode, and the off-potential is negative with respect to the source potential, and
in the second condition, the on-potential and the off-potential are positive with respect to the source potential, and a first difference between the off-potential and the source potential is smaller than a second difference between the on-potential and the source potential.

### Technical Proposal 9

The inspection apparatus according to any one of Technical proposals 1-8, wherein
the semiconductor member includes SiC.

### Technical Proposal 10

The inspection apparatus according to any one of Technical proposals 1-9, wherein
the controller is configured to further perform another first progress operation after the second operation, and
the controller is configured to further perform another second operation after the other first progress operation.

### Technical Proposal 11

The inspection apparatus according to any one of Technical proposals 1-10, wherein
the controller is configured to simultaneously perform at least portion of the first operation for a plurality of the semiconductor devices, and
the controller is configured to simultaneously perform at least a portion of the first progress operation for the plurality of semiconductor devices.

### Technical Proposal 12

The inspection apparatus according to any one of Technical proposals 1-11, further comprising:
a drain probe configured to be electrically connected to the drain electrode; and
a gate probe configured to be electrically connected to the gate electrode.

### Technical Proposal 13

An inspection system, comprising:
a controller configured to be electrically connected to a semiconductor device; and
a memory,
the semiconductor device including a semiconductor member, a transistor section, and a diode section,
the transistor section and the diode section being provided in the semiconductor member,
the transistor section including a source electrode, a drain electrode, and a gate electrode,
the diode section including a first end and a second end,
the first end being electrically connected to the source electrode,
the second end being electrically connected to the drain electrode,
the controller being configured to perform a first operation,
a first progress operation, a second operation, and a first determination operation,
the first progress operation being performed after the first operation,
the second operation being performed after the first progress operation,
in the first operation, the controller being configured to set the gate electrode to an on-potential and to detect a first detection value of a drain potential of the drain electrode in a state where a current source is electrically connected to the drain electrode, the current source supplying a first current to the drain electrode in a direction from the drain electrode to the source electrode,
in the first progress operation, the controller being configured to set the gate electrode to an off-potential in a state where the current source is electrically connected to the drain electrode,
in the second operation, the controller being configured to set the gate electrode to the on-potential and to detect a second detection value of the drain potential in a state where the current source is electrically connected to the drain electrode, and
in the first determination operation, the controller being configured to inspect the semiconductor device based on a difference between the first detection value and the second detection value.

### Technical Proposal 14

An inspection method for inspecting a semiconductor device, the semiconductor device including a semiconductor member, a transistor section, and a diode section, the transistor section and the diode section being provided in the semiconductor member, the transistor section including a source electrode, a drain electrode, and a gate electrode, the diode section including a first end and a second end, the first end being electrically connected to the source electrode, and the second end being electrically connected to the drain electrode, the method comprising:
performing a first operation, a first progressing operation, a second operation, and a first determination operation,
the first progress operation being performed after the first operation,
the second operation being performed after the first progress operation,
in the first operation, setting the gate electrode to an on-potential and detecting a first detection value of a drain potential of the drain electrode in a state where a current source is electrically connected to the drain electrode, the current source supplying a first current to the drain electrode in a direction from the drain electrode,
in the first progress operation, setting the gate electrode to an off-potential in a state where the current source is electrically connected to the drain electrode,
in the second operation, in a state where the current source is electrically connected to the drain electrode, setting the gate electrode to the on-potential, and detecting a second detection value of the drain potential, and
in the first determination operation, inspecting the semiconductor device based on a difference between the first detection value and the second detection value.

### Technical Proposal 15

The inspection method according to Technical proposal 14, wherein
a first progress period of the first elapsed operation is longer than a second period of the second operation.

### Technical Proposal 16

The inspection method according to Technical proposal 14, wherein
the first detection value is detected at a first end time of a first period of the first operation, and
the second detection value is detected at the second end time of a second period of the second operation.

### Technical Proposal 17

The inspection method according to any one of Technical proposals 14-16, wherein
the on-potential and the off-potential satisfy a first condition or a second condition,
in the first condition, the on-potential is positive with respect to a source potential of the source electrode, and the off-potential is negative with respect to the source potential, and
in the second condition, the on-potential and the off-potential are positive with respect to the source potential, and a first difference between the off-potential and the source potential is smaller than a second difference between the on-potential and the source potential.

### Technical Proposal 18

The inspection method according to any one of Technical proposals 14-17, wherein
the semiconductor member includes SiC.

### Technical Proposal 19

A method for manufacturing a semiconductor device, comprising:
manufacturing the semiconductor device; and
inspecting the semiconductor device by performing the inspection method according to any one of Technical proposals 14-17.

### Technical Proposal 20

The method for manufacturing the semiconductor device according to Technical proposal 19, wherein
the semiconductor member includes SiC.

According to the embodiments, it is possible to provide an inspection apparatus, an inspection system, an inspection method, and a method for manufacturing a semiconductor device that can improve efficiency.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the inspection apparatus or the inspection systems such as controller, memory, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all inspection apparatuses, inspection systems, inspection methods, and methods for manufacturing semiconductor devices practicable by an appropriate design modification by one skilled in the art based on the inspection apparatuses, inspection systems, inspection methods, and methods for manufacturing semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An inspection apparatus, comprising:
a controller configured to be electrically connected to a semiconductor device,
the semiconductor device including a semiconductor member, a transistor section, and a diode section,
the transistor section and the diode section being provided in the semiconductor member,
the transistor section including a source electrode, a drain electrode, and a gate electrode,
the diode section including a first end and a second end,
the first end being electrically connected to the source electrode,
the second end being electrically connected to the drain electrode,
the controller being configured to perform a first operation, a first progress operation, a second operation, and a first determination operation,
the first progress operation being performed after the first operation,
the second operation being performed after the first progress operation,
in the first operation, the controller being configured to set the gate electrode to an on-potential and to detect a first detection value of a drain potential of the drain electrode in a state where a current source is electrically connected to the drain electrode, the current source supplying a first current to the drain electrode in a direction from the drain electrode to the source electrode,
in the first progress operation, the controller being configured to set the gate electrode to an off-potential in a state where the current source is electrically connected to the drain electrode,
in the second operation, the controller being configured to set the gate electrode to the on-potential and to detect a second detection value of the drain potential in a state where the current source is electrically connected to the drain electrode, and
in the first determination operation, the controller being configured to inspect the semiconductor device based on a difference between the first detection value and the second detection value.

2. The apparatus according to claim 1, wherein
a first progress period of the first progress operation is longer than a second period of the second operation.

3. The apparatus according to claim 2, wherein
a first period of the first operation is longer than the second period.

4. The apparatus according to claim 3, wherein
the first progress period is shorter than the first period.

5. The apparatus according to claim 1, wherein
the controller is configured to detect the first detection value at an arbitrary time in a first period of the first operation, and
the controller is configured to detect the second detection value at an arbitrary time in a second period of the second operation.

6. The apparatus according to claim 1, wherein
the controller is configured to detect the first detection value at a first end time of a first period of the first operation, and
the controller is configured to detect the second detection value at a second end time of a second period of the second operation.

7. The apparatus according to claim 1, further comprising:
the current source.

8. The apparatus according to claim 1, wherein
the on-potential and the off-potential satisfy a first condition or a second condition,
in the first condition, the on-potential is positive with respect to a source potential of the source electrode, and the off-potential is negative with respect to the source potential, and
in the second condition, the on-potential and the off-potential are positive with respect to the source potential, and a first difference between the off-potential and the source potential is smaller than a second difference between the on-potential and the source potential.

9. The apparatus according to claim 1, wherein
the semiconductor member includes SiC.

10. The apparatus according to claim 1, wherein
the controller is configured to further perform another first progress operation after the second operation, and the controller is configured to further perform another second operation after the other first progress operation.

11. The apparatus according to claim 1, wherein
the controller is configured to simultaneously perform at least portion of the first operation for a plurality of the semiconductor devices, and
the controller is configured to simultaneously perform at least a portion of the first progress operation for the plurality of semiconductor devices.

12. The apparatus according to claim 1, further comprising:
a drain probe configured to be electrically connected to the drain electrode; and
a gate probe configured to be electrically connected to the gate electrode.

13. An inspection system, comprising:
a controller configured to be electrically connected to a semiconductor device; and
a memory,
the semiconductor device including a semiconductor member, a transistor section, and a diode section,
the transistor section and the diode section being provided in the semiconductor member,
the transistor section including a source electrode, a drain electrode, and a gate electrode,
the diode section including a first end and a second end,
the first end being electrically connected to the source electrode,
the second end being electrically connected to the drain electrode,
the controller being configured to perform a first operation,
a first progress operation, a second operation, and a first determination operation,
the first progress operation being performed after the first operation,
the second operation being performed after the first progress operation,
in the first operation, the controller being configured to set the gate electrode to an on-potential and to detect a first detection value of a drain potential of the drain electrode in a state where a current source is electrically connected to the drain electrode, the current source supplying a first current to the drain electrode in a direction from the drain electrode to the source electrode,
in the first progress operation, the controller being configured to set the gate electrode to an off-potential in a state where the current source is electrically connected to the drain electrode,
in the second operation, the controller being configured to set the gate electrode to the on-potential and to detect a second detection value of the drain potential in a state where the current source is electrically connected to the drain electrode, and
in the first determination operation, the controller being configured to inspect the semiconductor device based on a difference between the first detection value and the second detection value.

14. An inspection method for inspecting a semiconductor device, the semiconductor device including a semiconductor member, a transistor section, and a diode section, the transistor section and the diode section being provided in the semiconductor member, the transistor section including a source electrode, a drain electrode, and a gate electrode, the diode section including a first end and a second end, the first end being electrically connected to the source electrode, and the second end being electrically connected to the drain electrode, the method comprising:
performing a first operation, a first progressing operation,
a second operation, and a first determination operation, the first progress operation being performed after the first operation,
the second operation being performed after the first progress operation,
in the first operation, setting the gate electrode to an on-potential and detecting a first detection value of a drain potential of the drain electrode in a state where a current source is electrically connected to the drain electrode, the current source supplying a first current to the drain electrode in a direction from the drain electrode,
in the first progress operation, setting the gate electrode to an off-potential in a state where the current source is electrically connected to the drain electrode,
in the second operation, in a state where the current source is electrically connected to the drain electrode, setting the gate electrode to the on-potential, and detecting a second detection value of the drain potential, and
in the first determination operation, inspecting the semiconductor device based on a difference between the first detection value and the second detection value.

15. The method according to claim 14, wherein
a first progress period of the first elapsed operation is longer than a second period of the second operation.

16. The method according to claim 14, wherein
the first detection value is detected at a first end time of a first period of the first operation, and
the second detection value is detected at the second end time of a second period of the second operation.

17. The method according to claim 14, wherein
the on-potential and the off-potential satisfy a first condition or a second condition,
in the first condition, the on-potential is positive with respect to a source potential of the source electrode, and the off-potential is negative with respect to the source potential, and
in the second condition, the on-potential and the off-potential are positive with respect to the source potential, and a first difference between the off-potential and the source potential is smaller than a second difference between the on-potential and the source potential.

18. The method according to claim 14, wherein the semiconductor member includes SiC.

19. A method for manufacturing a semiconductor device, comprising:
manufacturing the semiconductor device; and
inspecting the semiconductor device by performing the inspection method according to claim 14.

20. The method according to claim 19, wherein
the semiconductor member includes SiC.
